(19) United States
(12) Patent Application Publication
(10) Pub. No.: US 2011/0168438 A1
(43) Pub. Date: Jul. 14, 2011

(54) INTERCONNECTION STRUCTURE AND METHOD THEREOF

(75) Inventor: Jung-Chien Chang, Xinzhuang City (TW)

(73) Assignee: MUTUAL-TEK INDUSTRIES CO., LTD., Xinzhuang City (TW)

(21) Appl. No.: 13/069,874

(22) Filed: Mar. 23, 2011

Related U.S. Application Data
(62) Division of application No. 12/045,362, filed on Mar. 10, 2008.

(30) Foreign Application Priority Data
Mar. 19, 2007 (TW) 96109328

(51) Int. Cl. H05K 1/11; H01R 43/00

(52) U.S. Cl. 174/262; 29/825

(57) ABSTRACT

The present invention discloses an interconnection structure which is formed by a method comprising providing a first conductive substrate, a second conductive substrate, and an insulating substrate; respectively forming a first circuit and a second circuit on the first conductive substrate and the second conductive substrate; forming a conductive bump on the second circuit; and connecting the insulating substrate with the first circuit and the second circuit by pressing the first conductive substrate, the insulating substrate and the second conductive substrate, wherein the conductive bump penetrates the insulating substrate to contact the first circuit.

### CROSS REFERENCE TO RELATED APPLICATIONS

This application is a divisional application of pending U.S. patent application Ser. No. 12/045,362, filed Mar. 18, 2008 and entitled “INTERCONNECTION STRUCTURE AND METHOD THEREOF”, which application claims the right of priority based on Taiwan Patent Application No. 096109328 entitled “INTERCONNECTION STRUCTURE AND METHOD THEREOF”, filed on Mar. 19, 2007. U.S. patent application Ser. No. 12/045,362 and Taiwan Patent Application No. 096109328 are incorporated herein by reference and assigned to the assignee herein.

### TECHNICAL FIELD

The present invention relates to an interconnection structure and more particularly, to an interconnection structure formed by pressing.

### BACKGROUND OF THE INVENTION

Printed circuit boards are mechanisms with circuit patterns for connecting various electronic components. FIG. 1 illustrates a schematic view of a traditional printed circuit board 10 with multiple layers. The printed circuit board 10 includes circuit layers 11, 12, and 13 and insulating layers 14 and 15 interposed there between. Conventionally, in order to electrically interconnect the different circuit layers 11, 12 and 13, a through hole 16 penetrating the corresponding layers is formed; and then a conductive layer 17 is plated on the sidewall 18 of the through hole 16, thereby creating electrical interconnections between the different circuit layers as shown in FIG. 1.

Generally, the effectiveness of the electrical interconnections depends upon the plating performance, which relates to the aspect ratio of the through hole 16. As shown in FIG. 1, the aspect ratio is defined as a ratio of the depth D to the diameter R, wherein the depth D is the depth of the through hole 16 in the direction along the thickness of the printed circuit board 10 and the diameter R is referred to the cross section of the through hole 16. When the aspect ratio of the though hole increases, the plating performance reduces since flowing plating chemicals into the through hole 16 becomes more difficult. This may result in a non-uniform plated layer, for example, like the conductive layer 17 on the sidewall 18 as shown in FIG. 1. The non-uniform conductive layer 17 acts adversely on electrical interconnections. That is, the conventional plating technology is not suitable for high-density printed circuit boards with high aspect ratios. Therefore, it is desired to provide inventive methods and structures to address the issues caused by the conventional methods.

### SUMMARY OF THE INVENTION

One aspect of the present invention is to provide an interconnection structure having conductive bumps. The interconnection structure is fabricated by forming the conductive bumps on one of the circuit layers; and then forcing the conductive bumps to penetrate an insulating layer and connect another circuit layer by pressing the circuit layers to the insulating layer. The present invention also provides another method comprising forming circuit layers on temporary substrates; embedding the circuit layers into an insulating layer by pressing the temporary substrates to the insulating layer; and then removing the temporary substrates to obtain a printed circuit board having a thickness as thin as the insulating layer.

In one embodiment, the present invention provides an interconnection structure for a printed circuit board. The interconnection structure includes an insulating substrate; a first circuit exposed on a first surface of the insulating substrate; a second circuit exposed on a second surface of the insulating substrate: and a first conductive bump connecting the first circuit and the second circuit, wherein the first circuit, the second circuit and the first conductive bump are embedded in the insulating substrate.

In another embodiment, the present invention provides a method for manufacturing an interconnection structure. The method includes the steps of providing a first conductive substrate, a second conductive substrate, and an insulating substrate; respectively forming a first circuit and a second circuit on the first conductive substrate and the second conductive substrate; forming a conductive bump on the second circuit; and connecting the insulating substrate with the first circuit and the second circuit by pressing the first conductive substrate, the insulating substrate and the second conductive substrate, wherein the conductive bump penetrates the insulating substrate to contact the first circuit.

### BRIEF DESCRIPTION OF THE DRAWINGS

The present invention will now be described, by way of examples, with reference to the accompanying drawings, in which:

FIG. 1 illustrates a schematic view of a conventional interconnection structure for a printed circuit board;

FIG. 2A to FIG. 2C illustrate schematic views of a method for manufacturing a first circuit in accordance with a first embodiment of the present invention;

FIG. 3A to FIG. 3C illustrate schematic views of a method for manufacturing a second circuit in accordance with the first embodiment of the present invention;

FIG. 3D to FIG. 3G illustrate schematic views of a method for manufacturing a first conductive bump on the second circuit in accordance with the first embodiment of the present invention;

FIG. 4A to FIG. 4C illustrate schematic views of a method for manufacturing a printed circuit board with two circuit levels in accordance with the first embodiment of the present invention;

FIG. 5A to FIG. 5B illustrate schematic views of a method for manufacturing a second conductive bump in accordance with a second embodiment of the present invention; and

FIG. 6A to FIG. 6B illustrate schematic views of a method for manufacturing a printed circuit board with four circuit levels in accordance with the second embodiment of the present invention.

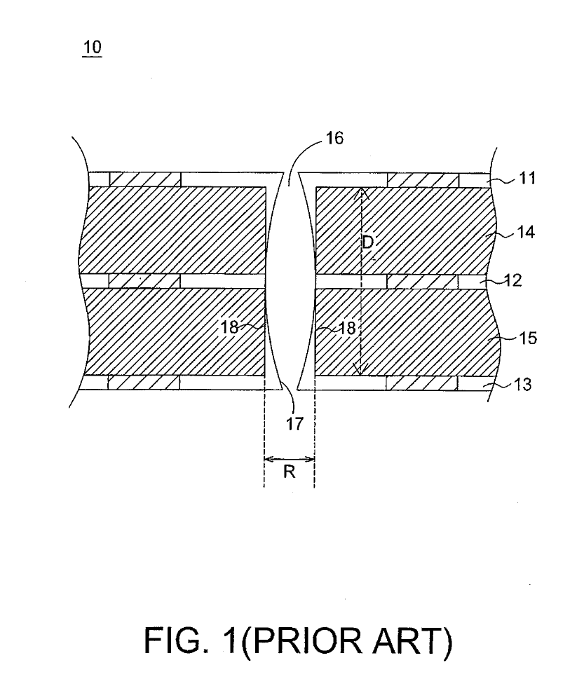

### DETAILED DESCRIPTION OF THE PREFERRED EMBODIMENTS

The preferred embodiments of the present invention will now be described in greater details by referring to the drawings that accompany the present application. It should be noted that the features illustrated in the drawings are not necessarily drawn to scale. Descriptions of well-known components, materials, and process techniques are omitted so as not to unnecessarily obscure the embodiments of the invention.

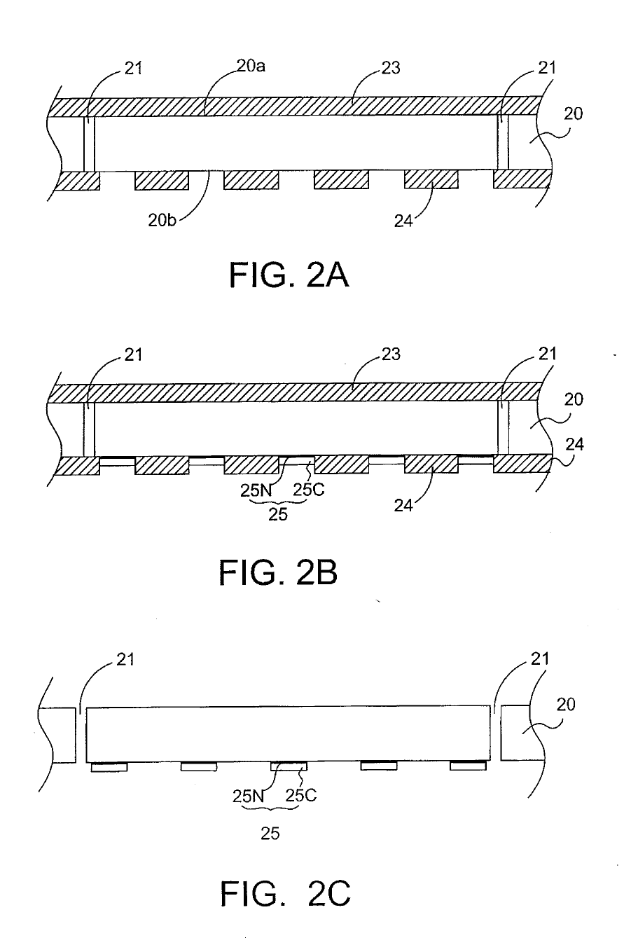

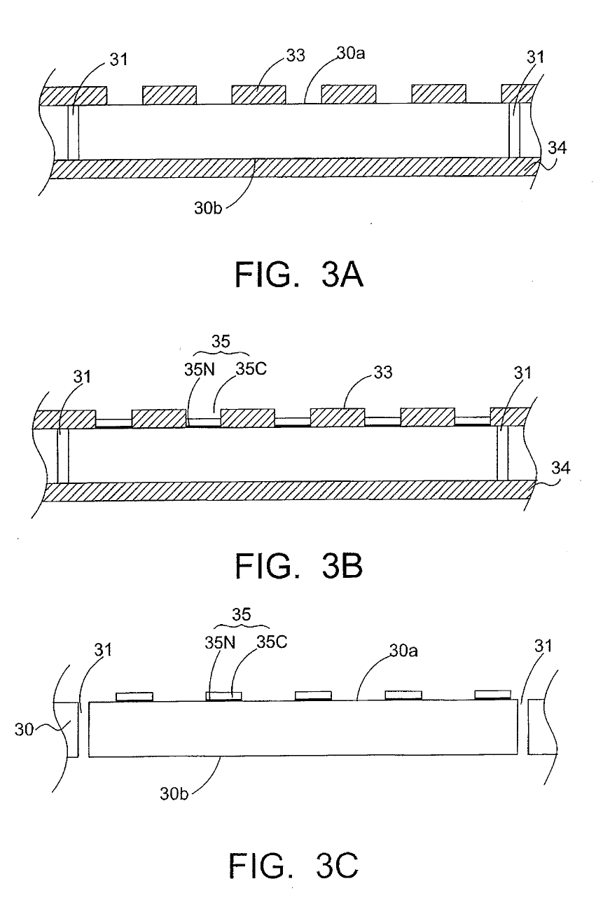

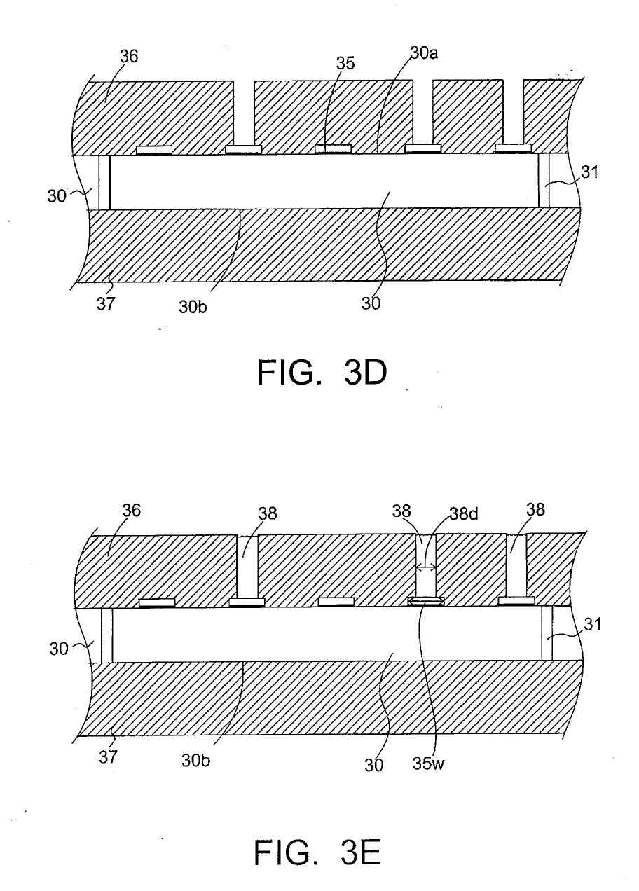

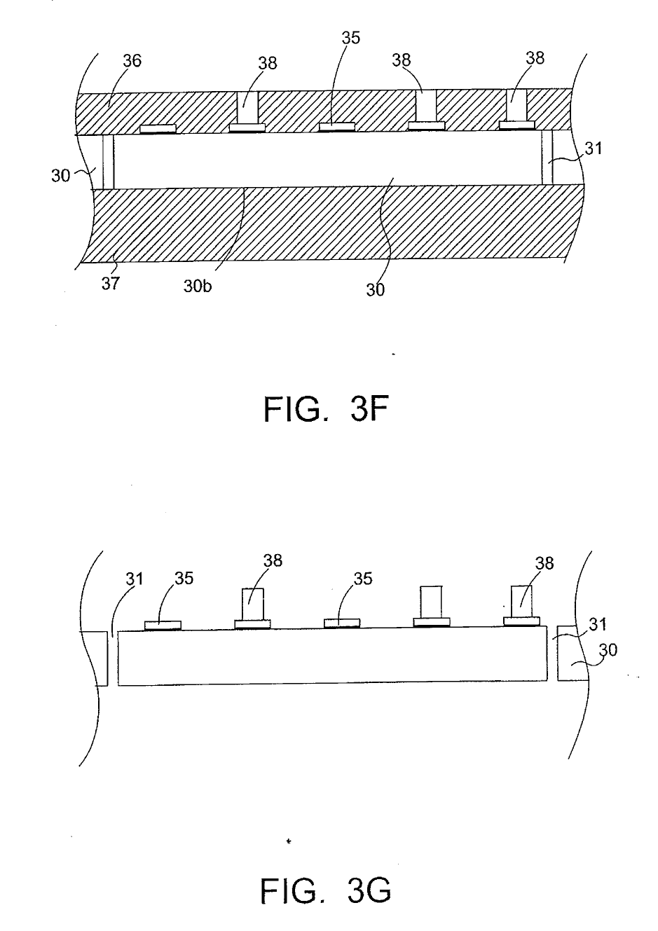

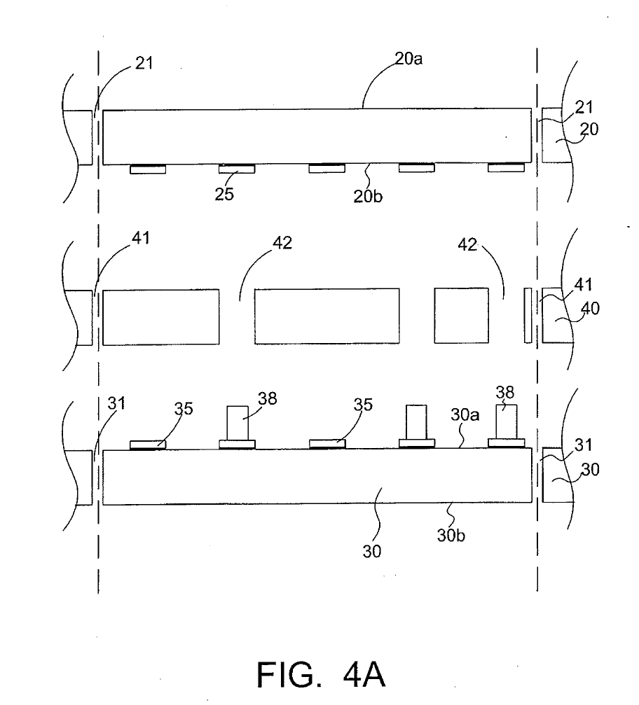

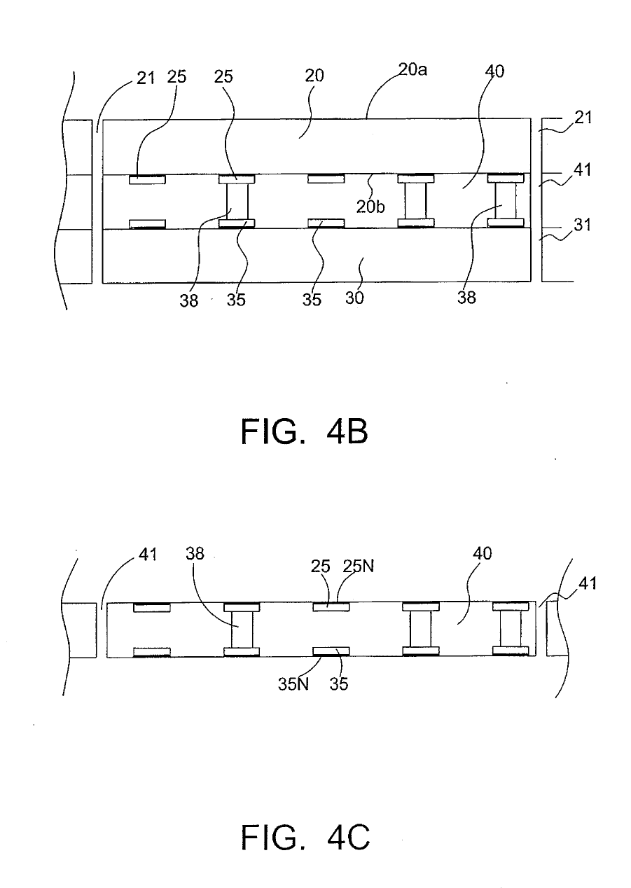

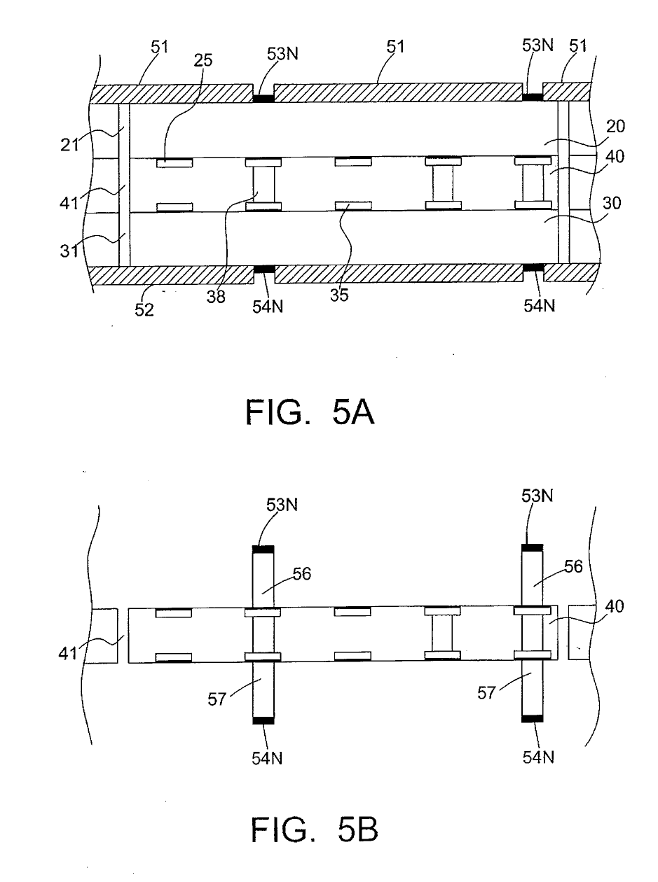

FIG. 2A to FIG. 2C, FIG. 3A to FIG. 3G and FIG. 4A to 4C schematically illustrate the first embodiment of the present invention, wherein FIG. 2A to FIG. 2C are directed to a first circuit 25 formed on a first conductive substrate 20.

As shown in FIG. 2A, a first conductive substrate 20 is provided. The first conductive substrate includes an alignment hole 21 to be used later. An un-patterned photoresist layer 23 and a first patterned photoresist layer 24 are respectively formed on the surface 20a and the surface 20b of the first conductive substrate 20. The first conductive substrate 20 can be a copper foil, or be made of any other suitable conductive materials. The thickness of the first conductive substrate 20 can vary, for example, about 0.1 mm in this embodiment. The photoresist layers 23 and 24 can be conventional dry films for preparing ordinary printed circuit boards. The thicknesses of the photoresist layers 23 and 24 are not limited, which can be, for example, around 25 μm and 40 μm. Note that for illustration purposes, plating is used for circuit formations in all embodiments of the present invention. It should be understood that the circuit formations also can be performed by any other suitable methods, for example, by printing the Ag gel or Cu gel on the related substrate, which are also included in the present invention.

Referring to FIG. 2B, using the photoresist layers 23 and 24 as masks, a first circuit 25 is formed on the first conductive substrate 20 by plating a conductive material in the openings of the first patterned photoresist layer 24. Preferably, the first circuit 25 can include an anti-etch layer 25N and a conductive layer 25C. The anti-etch layer 25N can be a Ni layer with a thickness between 25 μm and 50 μm, and the conductive layer 25C can be a Cu layer with a thickness between 50 μm and 100 μm. The line width of the first circuit 25 is preferably between 15 μm and 100 μm. In the first embodiment, the line width of the first circuit 25 is 30 μm. Note that the photoresist layers 23 and 24 are removed after forming the first circuit 25, as shown in FIG. 2C. The structure of FIG. 2C is to be used in subsequent steps.

FIG. 3A to FIG. 3C are directed to a second circuit 30 formed on a second conductive substrate 30.

As shown in FIG. 3A, a second conductive substrate 30 is provided. The second conductive substrate includes an alignment hole 31 corresponding to the alignment hole 21, which is to be used later. A second patterned photoresist layer 33 and an un-patterned photoresist layer 34 are respectively formed on the surface 30a and the surface 30b of the second conductive substrate 30. Referring to FIG. 3B, using the photoresist layers 33 and 34 as masks, a second circuit 35 is formed on the second conductive substrate 30 by plating a conductive material in the openings of the second patterned photoresist layer 33. Preferably, the line width of the second circuit 35 is between 15 μm and 100 μm. In the first embodiment, the line width of the second circuit 35 is 30 μm. Materials and thicknesses of the related layers for fabricating the second circuit 35 are similar to those for the first circuit 35 as aforementioned. Note that the photoresist layers 33 and 34 are removed after forming the second circuit 35, as shown in FIG. 3C.

FIG. 3D to FIG. 3G illustrate a method for forming a first conductive bump 38 on the second circuit 35.

As shown in FIG. 3D, a third patterned photoresist layer 36 and an un-patterned photoresist layer 37 are respectively formed on the surface 30a and the surface 30b of the second conductive substrate 30. A portion of the second circuit 35 is covered by the third patterned photoresist layer 36 while another portion of the second circuit 35, which is reserved for forming a first conductive bump 38 thereon, is exposed. Materials of the photoresist layers 36 and 37 can be similar to the photoresist layers 33 and 34. Note that the thickness of the third patterned photoresist layer 36 is critical depending upon the thickness of the first conductive bump 38 to be formed later. The third patterned photoresist layer 36 is preferably thicker than that of the photoresist layer 33 or 34. For example, the preferred thickness of the third patterned photoresist layer 36 is between 45 μm and 70 μm.

Referring to FIG. 3E, using the photoresist layers 36 and 37 as masks, the first conductive bump 38s are formed on the second circuit 35 by plating conductive materials in the openings of the third patterned photoresist layer 36. In FIG. 3E, a diameter 38d is defined with reference to the cross section of the conductive bump 38 along the line width 35w of the first circuit 35. Note that, the diameter 38d is preferably less than the width 35 w of the first circuit 35. Such a preferred design can increase the misalignment tolerance in the subsequent pressing steps and consequently reduce short circuits that might occur when mistakenly connecting the conductive bumps 38 with the undesired electrical joints. The conductive bumps 38 can be made of copper or any suitable conductive materials. The thickness of the conductive bump 38 depends upon an insulating substrate 40 to be used. In the first embodiment, the preferred thickness of the conductive bump 38 is between 45 μm and 70 μm.

FIG. 3F illustrates an optional step, which demonstrates planarizing the surface of the first conductive bumps 38 by polishing, which may also adjust the thickness of the conductive bump 38 to a desired value. FIG. 3G illustrates the step of removing the photoresist layers 36 and 37. The resultant structure of FIG. 3G is to be used in subsequent steps.

FIG. 4A to FIG. 4C illustrate a method for connecting the first circuit 25, the second circuit 35, and the insulating substrate 40, wherein the conductive bumps 38 penetrate the insulating substrate 40 to contact the first circuit 25.

As shown in FIG. 4A, the insulating substrate 40 is disposed between the first conductive substrate 20 of FIG. 2C and the second conductive substrate 30 of FIG. 3G, and opposite sides of the first circuit 25, the second circuit 35 or the conductive bumps 38 are set to face the insulating substrate 40. The insulating substrate 40 is formed with an alignment hole 40 corresponding to the alignment holes 21 and 31, as indicated by a dotted line. Preferably, the insulating substrate 40 can be a sheet made of polymers, such as epoxy resins or polyimide resins, with a thickness between 45 μm and 70 μm. In other embodiments, the insulating substrate 40 may contain reinforced materials, for example, glass fibers. Note that, as shown in FIG. 4A, the insulating substrate 40 is further formed with openings 42 corresponding to the first conductive bumps 38. The openings 42 provide spaces for the first conductive bumps 38 to penetrate the insulating substrate 40. Conventional laser drilling techniques can perform the step of forming the openings 42.

FIG. 4B illustrates the step of pressing the first conductive substrate 20, the insulating substrate 40 and the second conductive substrate 30. Preferably, the insulating substrate 40 is heated to soften polymers contained therein before pressing. The temperature for softening depends upon the glass transition temperature of the polymers. In the first embodiment, the pressure for pressing is set at around 20 Kg/cm² to 40 Kg/cm². Note that during the pressing operation, some fluids of the polymers may flow out of the edge of the substrates. After the heating and the pressing, the insulating substrate 40 connects the first circuit 25 and the second circuit 35 as adhesions generated from the softened polymers. Furthermore, since the softened polymers are fluid and movable, the first circuit 25 and the second circuit 35 are embedded in the insulating substrate 40. In the first embodiment, the conductive bumps 38 are in contact with the first circuit 25 by penetrating the insulating substrate 40 through the openings 42. Note that the step of forming the openings 42 prior to the pressing can be omitted if the heated insulating substrate 40, regardless of containing reinforced materials or not, is adapted to be penetrated directly by the conductive bumps.

FIG. 4C illustrate the step of removing the first conductive substrate 20 and the second conductive substrate 30 after the pressing step of FIG. 4B. The removing step is preferably preformed by etching. After removing the first conductive substrate 20 and the second conductive substrate 30, the anti-etch layers 25N and 35N can be optionally stripped by appropriate wet chemicals. FIG. 4C shows the resultant printed circuit board with two circuit layers 25 and 35 according to the first embodiment, wherein the thickness of the printed circuit board is substantially as thin as the single insulating substrate 40.

FIG. 5A to FIG. 5B illustrate a method for manufacturing second conductive bumps 56 and 57 in accordance with the second embodiment of the present invention. Compared with the first embodiment, the first conductive substrate 20 and the second conductive substrate 30 in the second embodiment are removed partially rather than completely. A portion of the first conductive substrate 20 and the second conductive substrate 30 remain for creating the second conductive bumps 56 and 57.

Specifically, as shown in FIG. 5A, fourth patterned photoresist layers 51 and 52 are formed on the first conductive substrate 20 and the second conductive substrate 30 of the structure of FIG. 4B. Then, using the fourth patterned photoresist layers 51 and 52 as masks, anti-etch layers 53N and 54N are plated on the first conductive substrate 20 and the second conductive substrate 30. Materials for the photoresist layers 51 and 52 are similar to the photoresist layers 23 and 24 as aforementioned. The anti-etch layer 53N and 54N can be Ni layers or any other suitable materials with a preferred thickness between 5 μm and 25 μm.

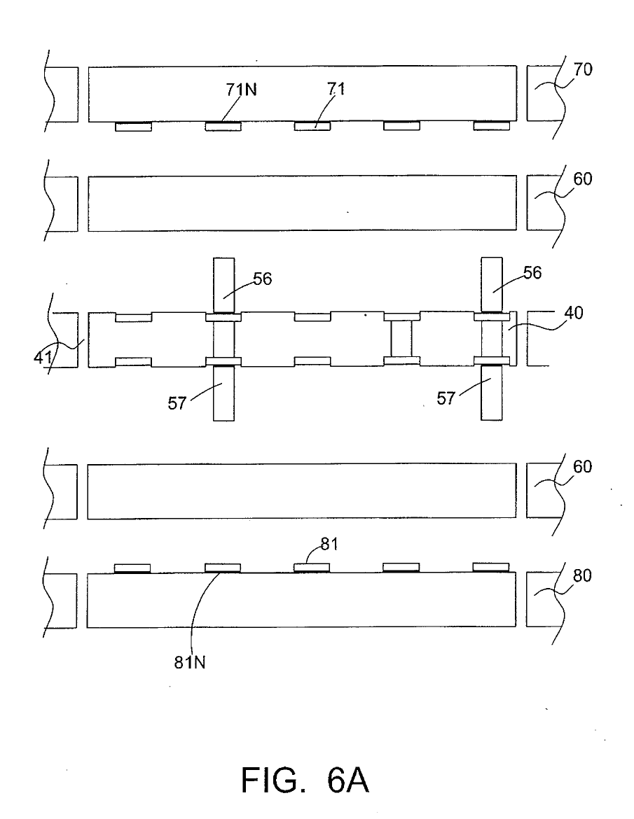

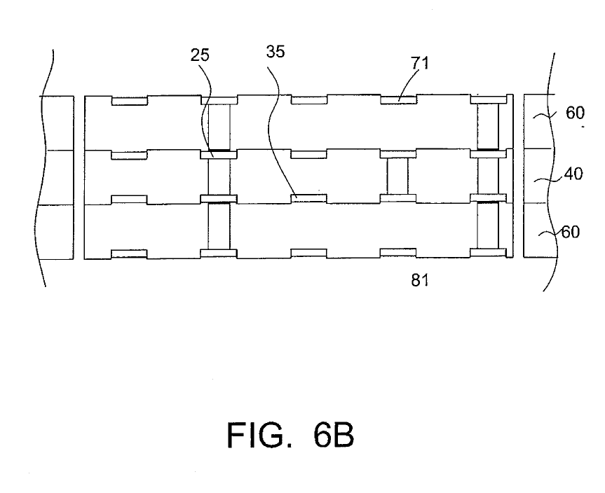

Referring to FIG. 5B, the fourth patterned photoresist layers 51 and 52 are first removed. Then, using the anti-etch layers 53N and 54N as masks, the second conductive bumps 56 and 57 are created by etching the first conductive substrate 20 and the second conductive substrate 30. Next, the anti-etch layers 53N and 54N and the remaining anti-etch layers are stripped using appropriated wet chemicals. The resultant structure after stripping is shown in FIG. 6A.

FIG. 6A illustrates a third conductive substrate 70 with the third circuit 71; one insulating substrate 60; the insulating substrate 40 with the second conductive bumps 56 and 57; another one insulating substrate 60; and a fourth conductive substrate 80 with the fourth circuit 81, which are arranged in sequence for pressing. Details for manufacturing the third conductive substrate 70 and the fourth conductive substrate 80 are similar to the descriptions of FIG. 2A to FIG. 2C. Details for pressing techniques are similar to the descriptions of FIG. 4A and FIG. 4B.

FIG. 6B illustrates the resultant structure after pressing the substrates as shown in FIG. 6A, followed by removing the third conductive substrate 70 and the fourth conductive substrate 80, and stripping off the anti-etch layers 71N and 81N. Note that, the third circuit 71 and the fourth circuit 81 are embedded in the insulating substrates 60. That is, FIG. 6B shows the resultant printed circuit board with four circuit layers according to the second embodiment, wherein the thickness of the printed circuit board is substantially as thin as the combination of the insulating substrates 60, 40 and 60.

The detailed description of the above preferable embodiments describes the technical features and spirit of the present invention, and the disclosed preferable embodiments are not intended to limit the scope of the present invention. On the contrary, the preferable embodiments and their variations or equivalents all fall within the scope of the present invention. Therefore, the scope of the present invention should be most broadly explained according to the foregoing description and includes all possible variations and equivalents.

I claim:

1. A method for manufacturing an interconnection structure, the method comprising the steps of:
providing a first conductive substrate, a second conductive substrate, and an insulating substrate;
respectively forming a first circuit and a second circuit on the first conductive substrate and the second conductive substrate;
forming a conductive bump on the second circuit; and
connecting the insulating substrate with the first circuit and the second circuit by pressing the first conductive substrate, the insulating substrate and the second conductive substrate, wherein the conductive bump penetrates the insulating substrate to contact the first circuit.

2. The method according to claim 1, wherein the step of forming the conductive bump comprises:
forming a patterned photoresist layer on the second circuit; and
plating a conductive material on the second circuit.

3. The method according to claim 1, further comprising planarizing the conductive bump prior to the step of pressing.

4. The method according to claim 1, further comprising forming an opening in the insulating substrate prior to the step of pressing, wherein the conductive bump penetrates the insulating substrate through the opening.

5. The method according to claim 4, wherein the step of forming the opening is conducted by lasers drilling.

6. The method according to claim 1, further comprising heating the insulating substrate for softening polymers contained in the insulating substrate.

7. The method according to claim 1, wherein the first circuit and the second circuit are embedded in the insulating substrate via the step of pressing.

8. The method according to claim 1, further comprising removing the first conductive substrate and the second conductive substrate to expose the first circuit and the second circuit after the step of pressing.

9. The method according to claim 1, further comprising removing a portion of the first conductive substrate and remaining another portion of the first conductive substrate after the step of pressing.

10. An interconnection structure for a printed circuit board, wherein the interconnection structure is made by the method according to claim 1.
